(19) United States
(12) Patent Application Publication
(10) Pub. No.: US 2008/0112122 A1
(43) Pub. Date: May 15, 2008

(54) Mobile storage device mounting structure

(76) Inventor: Cheng-Chun Chang, Hsin-Tien City (TW)

Correspondence Address: TROXELL LAW OFFICE PLLC, 5205 LEESBURG PIKE, SUITE 1404, FALLS CHURCH, VA, 22041, US

(21) Appl. No.: 11/819,703

(22) Filed: Jun. 28, 2007

(30) Foreign Application Priority Data
Jul. 17, 2006 (TW) 095212490

(51) Int. Cl. H05K 5/02

(52) U.S. Cl. 361/683

(57) ABSTRACT

A mobile storage device mounting structure in which two positioning strips respectively fastened to the two opposite lateral sides of a mobile storage device by forcing the positioning pins of the positioning strips into the respective pin holes, and then the positioning strips are inserted with the mobile storage device into a box body to electrically connect the mobile storage device to a circuit board, and then a front cover and a rear cover are respectively fastened to the front and rear open sides of the box body and stopped against the ends of the positioning strips to hold the positioning strips and the mobile storage device firmly in place.

### BACKGROUND OF THE INVENTION

1. Field of the Invention

The present invention relates to a mobile storage device mounting structure for securing a mobile storage device, for example, a hard disk drive or CD-ROM in a box. The mounting structure holds the inserted mobile storage device positively in position without the use of any mounting screws.

2. Description of the Related Art

A mounting rack for mobile storage device is to be mounted in a case to hold a mobile storage device, for example, 2.5″, 2.5″ or 5.25″ mobile CD-ROM box, protecting the mobile storage device against vibration during reading or writing of the storage device, or against accidental impact during delivery of the apparatus.

A mounting rack for mobile storage device is generally comprised of two metal frame plates. The metal frame plates have elongated mounting slots respectively fastened to respective mounting scew holes on the two opposite lateral sides of the mobile storage device, and then the the mobile storage device is inserted with the metal frame plates into the case and electrically connected to a circuit board inside the case. Thereafter, screws are inserted through respective mounting through holes on the case and fastened to the metal frame plates to affix the metal frame plates and the mobile storage device to the inside of the case, and then front and back covers are respectively covered on the front and back side of the case.

FIG. 1 shows another mounting arrangement according to the prior art. According to this design, the box body A has a plurality of elongated mounting slots A1 on the bottom wall corresponding to respective mounting holes B1 on the bottom wall of the mobile storage device B. During installation, the signal and power terminal of the circuit board C is electrically connected to the nmobiel storage device B, and then screws are respectively inserted through the elongated mounting slots A1 and fastened to the mounting holes B1 to affix the mobile storage device B to the box body A, and then front cover D and back cover F are respectively fastened to the front and rear open sides of the box body A to finish the installation.

According to the aforesaid two conventional mounting arrangements, mounting screws must be used. The use of mounting screws complicates the installation procedure.

### SUMMARY OF THE INVENTION

The present invention has been accomplished under the circumstances in view. According to one aspect of the present invention, the mobile storage device mounting structure comprises a box body, a mobile storage device inserted into the box body, a front cover and a rear cover respectively fastened to the box body to close the front open side and rear open side of the box body, a circuit board mounted in the rear cover for the connection of the mobile storage device electrically, and a positioning structure for securing the mobile storage device inside the box body in place. The positioning structure comprises two positioning strips respectively fastened to the two opposite lateral sides of the mobile storage device. Each positioning strip has at least one positioning pin perpendicularly extending from the inner side and engaged into a respective pin hole on the mobile storage device, and two opposite ends respectively stopped against the front cover and the rear cover.

According to another aspect of the present invention, the positioning strips are injection molded from plastics.

According to still another aspect of the present invention, the positioning strips each have at least one reinforcing rib at the outer side opposite to the at least one positioning pin.

According to still another aspect of the present invention, the positioning strips each have at least one of the two opposite ends thereof capped with an elastic cap.

### BRIEF DESCRIPTION OF THE DRAWINGS

FIG. 1 is an exploded view of a mobile storage device mounting structure according to the prior art.

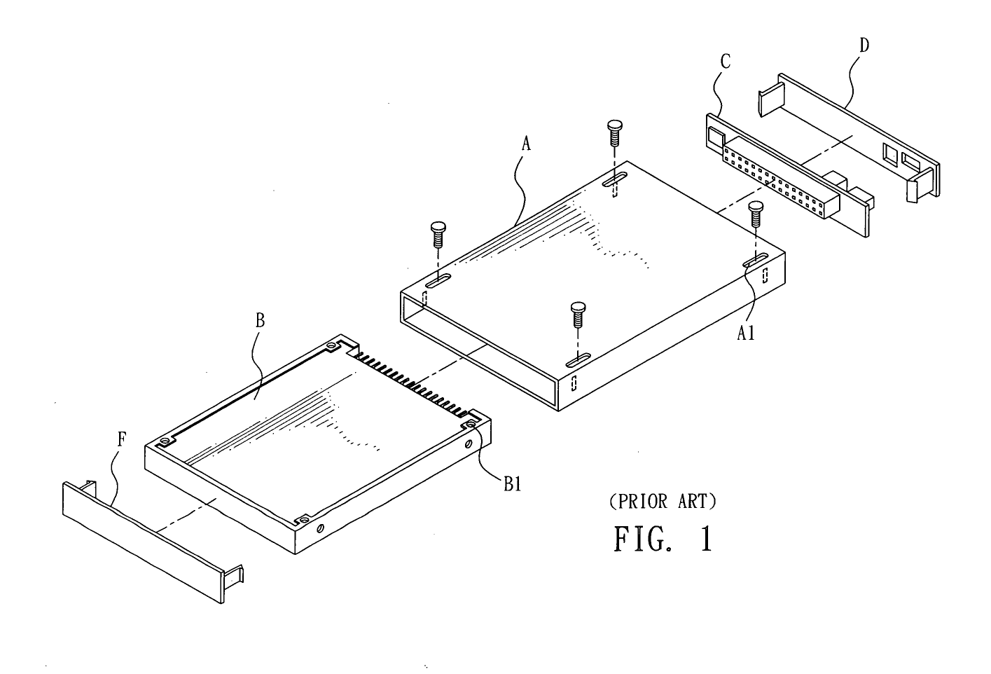

FIG. 2 is an exploded view of a mobile storage device mounting structure according to the present invention.

FIG. 3 is a top view partially in section of the mobile storage device mounting structure in accordance with the present invention.

### DETAILED DESCRIPTION OF THE PREFERRED EMBODIMENT

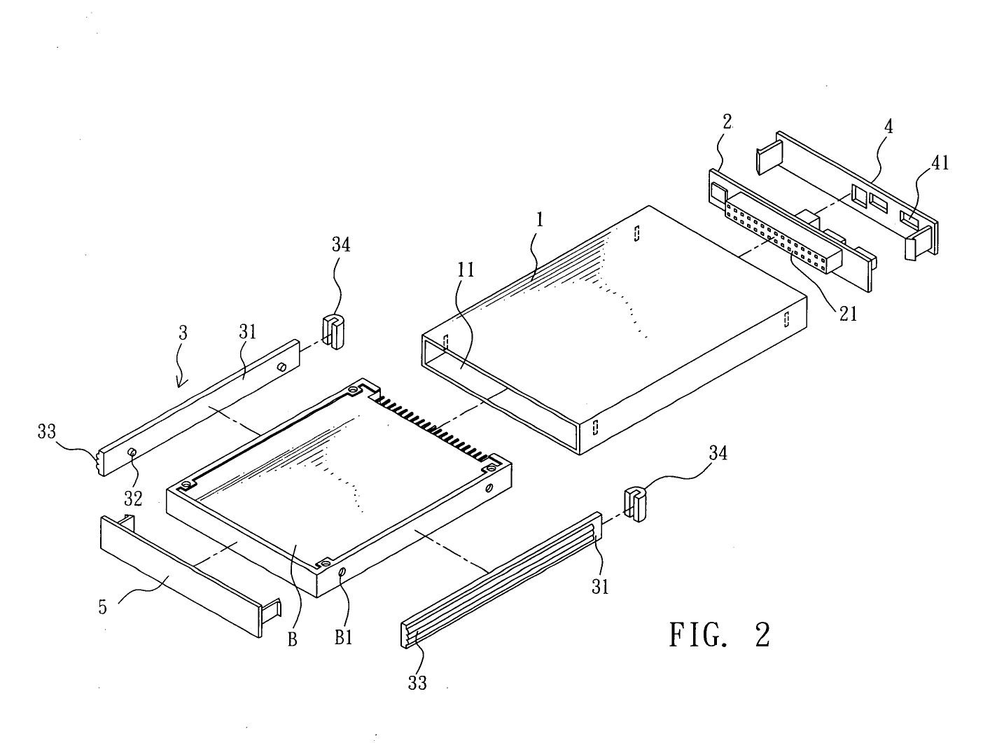

Referring to FIG. 2, a mobile storage device mounting structure in accordance with the present invention is shown comprised of a box body 1, a circuit board 2, a positioning device 3, a rear cover 4, and a front cover 5.

The box body 1 is a hollow container made in integrity by means of extrusion technology, or formed of top and half shells respectively injection molded from plastics. The box body 1 has an opening 11 on each of the front and rear sides.

The circuit board 2 is a conventional design, having a first electric connector 21 at an inner side for connection to the signal connection port of the mobile storage device B, and a second electric connector, for example, USB connector (not shown) at an outer side for connection to a computer directly or through a cable for transmitting signals. The circuit board 2 may be provided with a power input socket and a power switch at the outer side for power input on/off control, and a power output plug for connection to the power socket at the mobile storage device B to provide the mobile storage device B with the necessary working voltage.

The positioning device 3 is comprised of two symmetrical positioning strips 31. Each positioning strip 31 has at least one, for example, two positioning pins 32 perpendicularly extending from one side, namely, the inner side for engaging into respective locating holes B1 on the mobile storage device B, a plurality of reinforcing ribs 33 on the other side, namely, the outer side to reinforce the structural strength. The positioning strips 31 are preferably molded from plastics to reduce the cost. By means of inserting the positioning pins 32 of the positioning strips 31 into the locating holes B1 of the mobile storage device B, the positioning strips 31 are secured to the mobile storage device B at two sides. Further, elastic caps 34 may be selectively capped on the ends of the positioning strips 31 to assure positive contact of the ends of the positioning strips 31 with the rear cover 4 and the front cover 5.

The rear cover 4 is fastened to the box body 1 to close the opening 11 at the rear side of the box body 1, having openings 41 for receiving the second electric connector, power input socket and power switch of the circuit board 2. As illustrated, the circuit board 2 is fastened to the inner side of the rear cover 4 for the connection of the mobile storage device B.

The front cover 5 is fastened to the box body 1 to close the opening 11 at the front side of the box body 1.

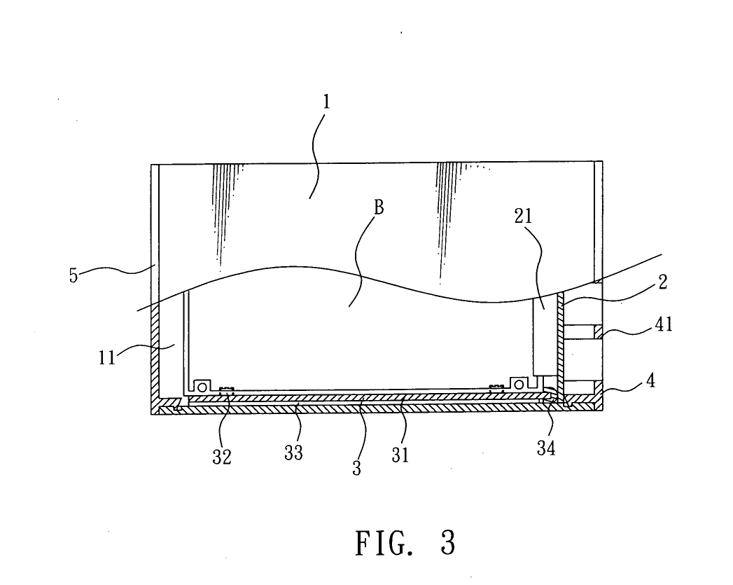

Referring to FIGS. 2 and 3, the positioning pins 32 of the positioning strips 31 are respectively inserted into the locating holes B1 of the mobile storage device B, and then the positioning strips 31 are inserted with the mobile storage device B into the box body 1, and then the circuit board 2 is carried on the rear cover 4 and electrically connected to the mobile storage device B, and then the front cover 5 and the rear cover 4 are fastened to the box body 1 and stopped against the ends of the positioning strips 31 to close the openings 11 of the box body 1 and to hold the positioning strips 31 firmly in place.

As stated above, the two positioning strips are stopped between the front and rear covers to hold the mobile storage device firmly inside the box body. This mounting procedure is quite simple and does not need any mounting screws. Further, the reinforcing ribs reinforce the structural strength of the positioning strips. Further, the installation of the elastic caps assure positive positioning of the positioning strips between the front cover and the rear cover.

Although a particular embodiment of the invention has been described in detail for purposes of illustration, various modifications and enhancements may be made without departing from the spirit and scope of the invention.

What is claimed is:

1. A mobile storage device mounting structure comprising a box body, said box body having a front open side and a rear open side, a mobile storage device inserted into said box body, a front cover and a rear cover respectively fastened to said box body to close the front open side and rear open side of said box body, a circuit board mounted in said rear cover for the connection of said mobile storage device electrically, and a positioning structure for securing said mobile storage device inside said box body in place, wherein said positioning structure comprises two positioning strips respectively fastened to two opposite lateral sides of said mobile storage device, said positioning strips each having at least one positioning pin perpendicularly extending from an inner side thereof and engaged into a respective pin hole on said mobile storage device and two opposite ends respectively stopped against said front cover and said rear cover.

2. The mobile storage device mounting structure as claimed in claim 1, wherein said positioning strips are injection molded from plastics.

3. The mobile storage device mounting structure as claimed in claim 1, wherein said positioning strips each have at least one reinforcing rib at an outer side thereof opposite to said at least one positioning pin.

4. The mobile storage device mounting structure as claimed in claim 1, wherein said positioning strips each have at least one of the two opposite ends thereof capped with an elastic cap.
